(19) United States
(12) Patent Application Publication
(10) Pub. No.: US 2016/0073492 A1
(43) Pub. Date: Mar. 10, 2016

(54) METHOD OF FORMING AN ANTI-CORROSION PROTECTIVE FILM

(71) Applicants: Inventec (Pudong) Technology Corporation, Shanghai (CN); INVENTEC CORPORATION, Taipei City (TW)

(72) Inventors: Chenghung WU, Taipei City (TW); Chien-Hua CHANG, Taipei City (TW); Shui-Ching CHU, Taipei City (TW); Wenchi CHEN, Taipei City (TW)

(21) Appl. No.: 14/677,570

(22) Filed: Apr. 2, 2015

(30) Foreign Application Priority Data
Sep. 5, 2014 (CN) 201410451805.8

(51) Int. Cl. H05K 1/02; H05K 3/00; H05K 1/11; H05K 3/46

(52) U.S. Cl. CPC H05K 1/0268; H05K 3/46; H05K 3/0091; H05K 3/0094; H05K 1/0298; H05K 1/115; H05K 2203/0548; H05K 2201/0367

(57) ABSTRACT

A forming method is to form an anti-corrosion protective film on a test contact of a substrate. The anti-corrosion protective film is to protect the test contact from corrosion. The forming method includes the steps of preparing a mask having at least one hole respective to the test contact, applying a printing process to print a metal paste onto the test contact through the hole of the mask, and applying a solder reflow process to melt and then solidify the metal paste so as to form the anti-corrosion protective film covering the test contact.

This application claims the benefit of China Patent Application Serial 201410451805.8, filed Sep. 5, 2014, the subject matter of which is incorporated herein by reference.

### BACKGROUND OF INVENTION

1. Field of the Invention

The invention relates to a method of forming an anti-corrosion protective film, and more particularly to a forming method of an anti-corrosion protective film that utilizes a solder reflow process to form an anti-corrosion protective film on a hole of a steel plate.

2. Description of the Prior Art

Recently, as the technology progresses every day, plenty of hi-tech electronic products are blooming in the marketplace. All of these electronic products have a common element, the printed circuit board (PCB), for planting various electronic components. In the art, materials suitable for the substrate of the PCB include electrolytic Ni/Au, organic solderability preservatives (OSP), immersion Ag, electroless Ni/Au, ENIG, and so on.

In all current manufacturing processes, various electronic components are planted to the substrate by the surface mount technology (SMT). In the SMT process, solder pastes are firstly printed to individual solder pads on the substrate through holes of a steel plate, then leads of each electronic component are planted on the corresponding solder paste, and finally a solder reflow oven is applied to melt the solder pastes so as to wrap the solder around the corresponding leads of the respective electronic component.

Generally, the PCB usually includes at least via (penetration hole) for electrically connecting two layers of the PCB and at least a test via for testing performed on an ICT (in-circuit tester). However, to increase the yield of the ICT test, naked coppers of the via or the test via won't have any printed solder paste. Therefore, while the PCB is in an atmosphere of ill air quality (for example, a sulfur-contained air) for a substantial period of time, the naked copper and the sulfur would react to form a Cu₂S, which will lead to creep corrosion eventually. As a creep corrosion occurs in the circuit board, the electric connection of a via or other wiring (for example, the port having the solder paste) would be vulnerable to be open and thus to fail the whole circuit board.

Furthermore, referring to FIG. 1, a schematic cross-sectional view of a portion of a conventional circuit board is shown. The conventional circuit board includes a substrate PA1, a concentric metal structure PA2 and a solder paste PA3. In the art, to protect external surfaces of the concentric metal structure PA2 from being oxidized or corroded, the solder paste PA3 is provided to top the metal structure PA2, and is further melted as a solid dome, after a solder reflow process, to shield both the metal structure PA2 and the corresponding via PA21. Though the surfaces of the concentric metal structure PA2 can be protected from being oxidized and corroded, yet the probe of the ICT testing would have difficulty in directly piecing through the solid solder paste PA3, and thus the corresponding testing would need additional and cost work in removing the solder paste PA3 prior to applying the probe.

### SUMMARY OF THE INVENTION

According to the conventional technology, in order to enhance the yield in ICT testing, the naked copper portion of the via and/or the test via would be formed free of the solder paste. However, as a consequence, the naked copper would be exploded to the environment containing the sulfur, and a possible sulfur-related reaction would happen to the naked copper and thus generate a Cu₂S to hurt the printed circuit board. Also, the solder paste on the test via for corrosion and oxidation protection would form a barrier for applying the probe into the via to be tested.

Accordingly, it is the primary object of the present invention to provide a method of forming an anti-corrosion protective film, which introduces a metal plate to construct holes corresponding to the test contact. The holes of the metal plate allow the metal paste to penetrate therethrough and then to be printed on the annual metal structure. A solder reflow process is applied finally to melt and then solidify the metal paste to form the anti-corrosion protective film covering the metal structure of the test contact.

In one embodiment of the present invention, a method of forming an anti-corrosion protective film is to form an anti-corrosion protective film on a test contact of a substrate. The method of forming an anti-corrosion protective film includes a step of preparing a mask having at least one hole corresponding to the test contact, a step of applying a printing process to print a metal paste onto the test contact through the hole of the mask, and a step of applying a solder reflow process to melt and then solidify the metal paste to form the anti-corrosion protective film covering the test contact.

In the present invention, the hole of the mask is to allow the metal paste to penetrate therethrough before being printed onto the test contact. After the solder reflow process, the anti-corrosion protective film covering the test contact is formed to provide effective protection upon the test contact from any corrosion.

In one embodiment of the present invention, the test contact includes a metal structure and a via, in which the via is located at the center of the metal structure. The hole of the mask is located respective to the metal structure so as to allow the metal paste to be printed properly on the metal structure. Preferably, the mask has a plurality of holes that are symmetrically arranged.

In the present invention, by aligning the holes of the mask with the annual metal structure, the metal paste can thus be printed properly onto the annual metal structure, and situation of the metal paste falling into the via can be effectively avoided. For the holes are symmetrically arranged, the metal paste can evenly distributed over the annual metal structure. In the solder reflow process, the metal paste would melt to flow and thus enlarge its coverage over the annual metal structure. Further, for the metal paste is evenly distributed over the annual metal structure, so original-separate metal pastes can be melted and further aggregated to form a unique broader area to cover at least a portion of the annual metal structure.

In one embodiment of the present invention, the metal paste is a solder paste.

In one embodiment of the present invention, a circuit board having an anti-corrosion protective film includes a substrate and the anti-corrosion protective film. The substrate further includes a test contact having a metal structure and a via, in which the via is located at the center of the metal structure. The anti-corrosion protective film is located above and covers the test contact.

In one embodiment of the present invention, the anti-corrosion protective film further includes at least pone perimeter bump portion and a central concave portion, in which the central concave portion is located above the via. Preferably, the perimeter bump portion and the central concave portion are integrated as a unique piece by having the perimeter bump portion to locate above the metal structure.

In one embodiment of the present invention, a circuit board having an anti-corrosion protective film includes a substrate and the anti-corrosion protective film. The substrate further includes a test contact further having a metal structure. The anti-corrosion protective film is located above and covers the test contact.

In one embodiment of the present invention, the anti-corrosion protective film further includes at least one perimeter bump portion and a central concave portion, in which the central concave portion is located on the metal structure. Preferably, the perimeter bump portion and the central concave portion are integrated as a unique piece by having the perimeter bump portion located above at least a portion of the metal structure.

All these objects are achieved by the method of forming an anti-corrosion protective film described below.

### BRIEF DESCRIPTION OF THE DRAWINGS

The present invention will now be specified with reference to its preferred embodiment illustrated in the drawings, in which:

FIG. 1 is a schematic cross-sectional view of a portion of a conventional circuit board;

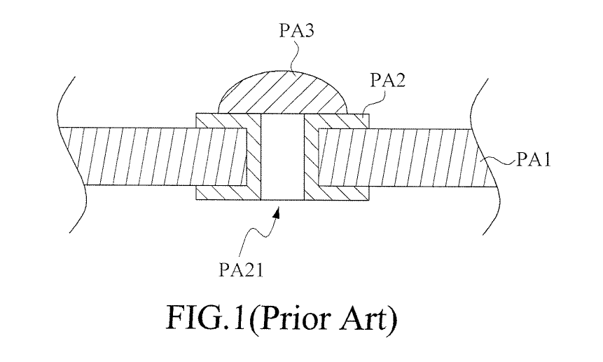

FIG. 2 demonstrates perspective a metal structure of a substrate and a separate mask with holes in accordance with the present invention;

FIG. 3 is a schematic cross-sectional view of an assembly of the mask and the substrate of FIG. 2, in which the mask is arranged on top of the substrate so as to allow metal pastes to be printed on the metal structure through the holes of the mask;

FIG. 4 is a schematic top view of the metal paste on the metal structure of FIG. 3;

FIG. 5 demonstrates another state of FIG. 4, in which an anti-corrosion protective film formed to cover the metal structure after a solder reflow process in accordance with the present invention is applied to the metal pastes printed on the metal structure;

FIG. 6 is a schematic cross-sectional view of FIG. 5;

FIG. 7 shows a schematic planar view of a second embodiment of the mask in accordance with the present invention;

FIG. 8 shows a schematic planar view of metal pastes printed on the test contact by applying the mask of FIG. 7;

FIG. 9 demonstrates another state of FIG. 8 after a solder reflow process;

FIG. 10 shows a schematic planar view of a third embodiment of the mask in accordance with the present invention;

FIG. 11 shows a schematic planar view of metal pastes printed on the test contact by applying the mask of FIG. 10; and

FIG. 12 demonstrates another state of FIG. 9 after a solder reflow process.

### DESCRIPTION OF THE PREFERRED EMBODIMENT

The invention disclosed herein is directed to a method of forming an anti-corrosion protective film. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

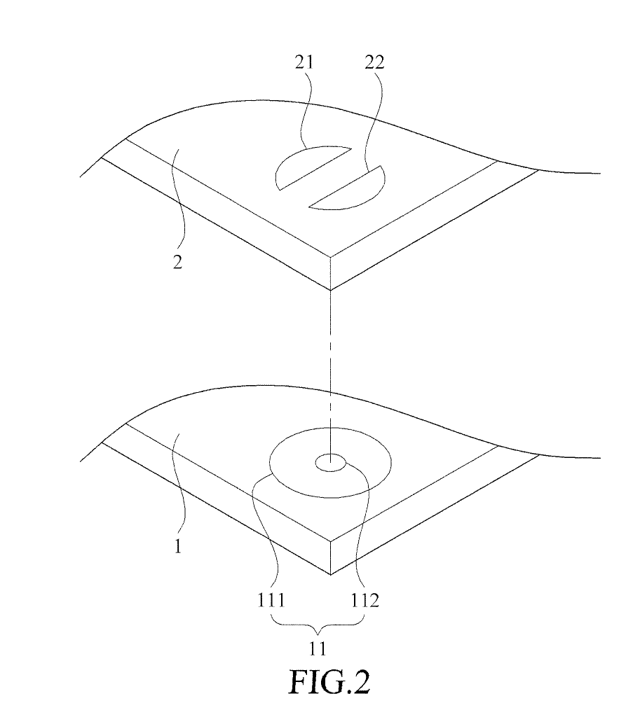

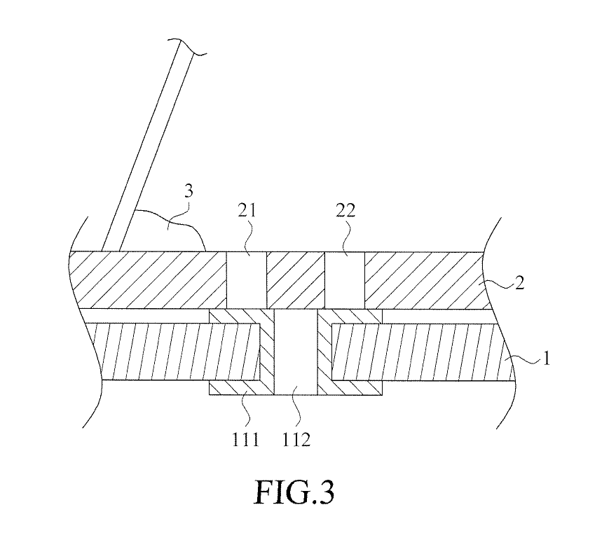

Refer now to FIG. 2 and FIG. 3, in which FIG. 2 demonstrates perspective a metal structure of a substrate and a separate mask with holes in accordance with the present invention and FIG. 3 is a schematic cross-sectional view of an assembly of the mask and the substrate of FIG. 2 by having the mask to be arranged on top of the substrate so as to allow metal pastes to be printed on the metal structure through the holes of the mask.

As shown, the method of forming an anti-corrosion protective film in accordance with the present invention is applied to a substrate 1, in which the substrate 1 further includes a test contact 11. The test contact 11 is consisted of a metal structure 111 and a via 112 constructed at the center of the metal structure 111. Preferably, the metal structure 111 is a concentric annual metal structure. While in performing the method of forming an anti-corrosion protective film, the first step is to prepare a mask 2, in which the mask 2 has two holes 21, 22, located respectively to the metal structure 111 of the test contact 11. In this embodiment shown in FIG. 2, the holes 21, 22 are a pair of symmetric half moon-shaped structures.

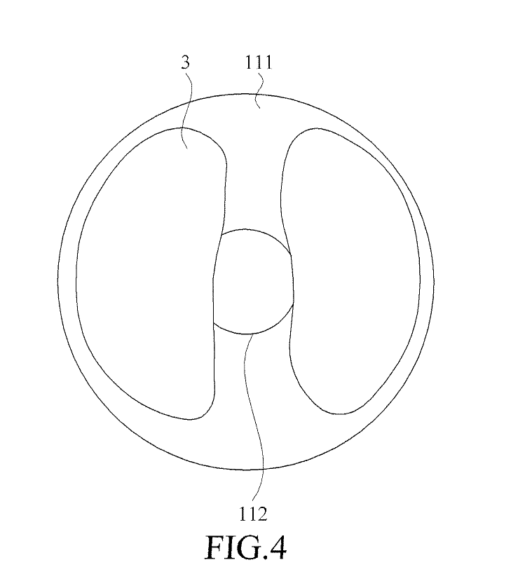

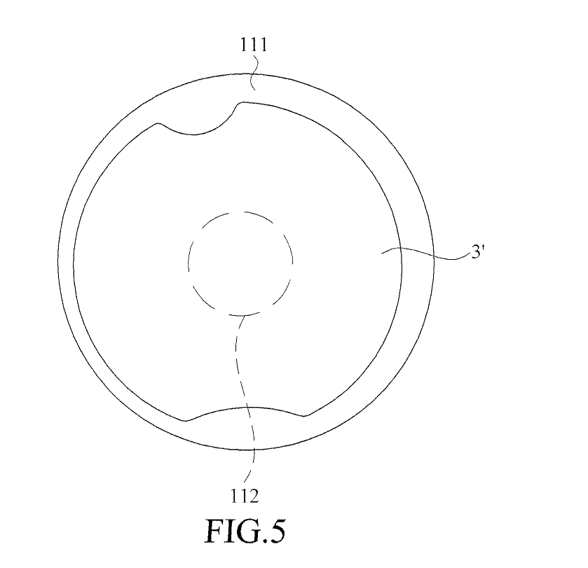

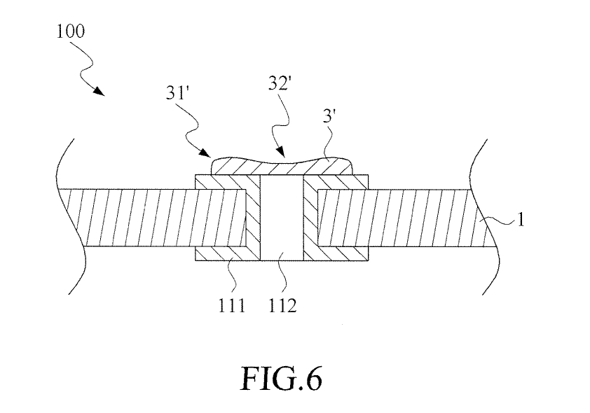

Refer now to FIG. 2 through FIG. 6, in which FIG. 4 is a schematic top view of the metal paste on the metal structure of FIG. 3, FIG. 5 demonstrates another state of FIG. 4 showing an anti-corrosion protective film formed to cover the metal structure after a solder reflow process in accordance with the present invention is applied to the metal pastes printed on the metal structure, and FIG. 6 is a schematic cross-sectional view of FIG. 5.

Then, the second step of the method is to apply a printing process to print a metal paste 3 onto the metal structure 111 of the test contact 11 through the hole 21, 22 of the mask 2. In this embodiment, two holes 21, 22 are applied so that the possibility of jamming the hole or position shifting during the printing can be substantially reduced. Preferably, the metal paste 3 of the present invention can be a solder paste.

Then, the third step of the method is to apply a solder reflow process to the metal paste 3 printed on the test contact 11. After annealing of the solder reflow process, the metal paste 3 is transformed into an anti-corrosion protective film 3′ to cover the test contact 11. In practice, the solder reflow process is mainly to arrange the substrate 1 printed with the metal paste 3 inside a solder reflow oven so as to melt the metal paste 3 (i.e. the solder paste) to cover the annual metal structure 111 in a broader area, such that the annual metal structure 111 can be protected from directly contacting the atmosphere and thus possible corrosion from oxides or sulfides can be avoided.

In the present invention, the holes 21, 22 of the mask 2 are used to allow the metal paste 3 to pass therethrough and to be further printed on the metal structure 111. Then, apply a solder reflow process to solidify the metal paste 3 into a form of the anti-corrosion protective film 3′ so as to have the anti-corrosion protective film 3′ to cover and thus protect the metal structure 111 from being oxidized or vulcanized. In this embodiment, for the metal paste 3 is the solder paste, and for the solder paste contains the flux that would aggregate the tin powders into groups, the metal paste 3 printed onto the metal structure 111 of the test contact 11 through the holes 21, 22 of the mask 2 would form two paste drops. Actually, the flux of the metal paste 3 does not distribute evenly across the drop. Precisely, the flux is mainly distributed at the perimeter of the paste drop, and is few in the central area thereof. While in the solder reflow process, the melted metal paste 3 would outflow aside so as to have the two paste drops 3 to connect together and form an anti-corrosion protective film 3′ in a shape as shown in FIG. 5. Upon such an arrangement, in a later testing, the probe would be easy to piece through the metal pastes 3 at the central area of the test contact 11 and thereby the testing can be performed without problems.

In addition, as shown in FIG. 6, the circuit board 100 having the anti-corrosion protective film includes the substrate 1 and the anti-corrosion protective film 3′. The substrate 1 has a test contact 11 (see FIG. 2), and the test contact 11 further includes a metal structure 111 and a via 112 constructed at the center of the metal structure 111. The anti-corrosion protective film 3′ covers the test contact 11 and is formed to have two perimeter bump portion 31′ and a central concave portion 32′. The central concave portion 32′ is positioned right above the via 112 and integrates the perimeter bump portion 31′ as a unique piece, while the perimeter bump portion 31′ is located above the metal structure 111.

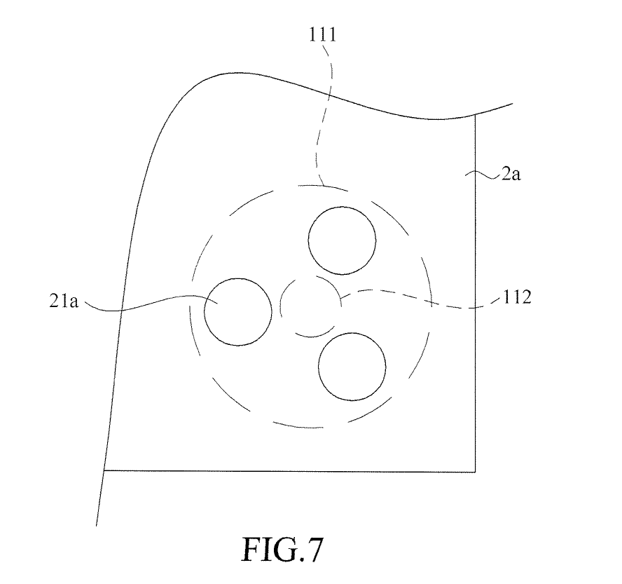

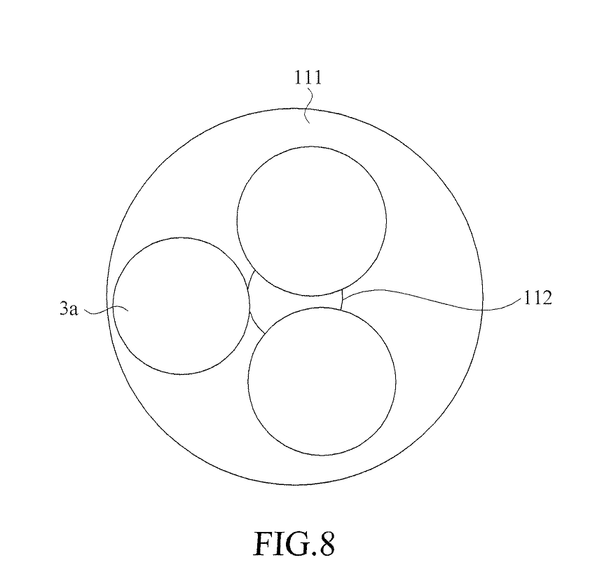

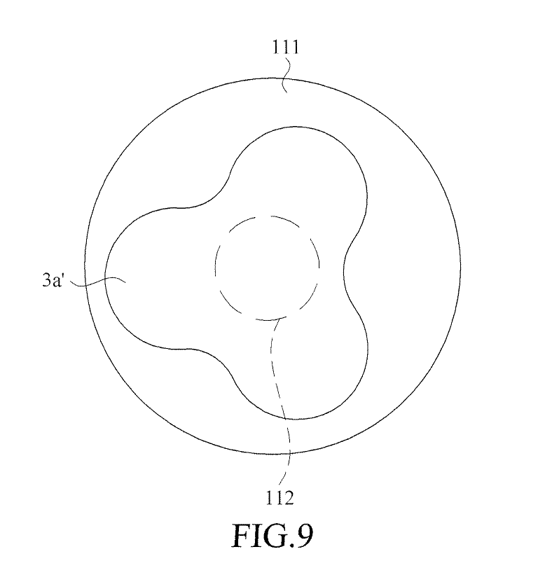

Refer now to FIG. 7 through FIG. 9, in which FIG. 7 shows a schematic planar view of a second embodiment of the mask in accordance with the present invention, FIG. 8 shows a schematic planar view of metal pastes printed on the test contact by applying the mask of FIG. 7, and FIG. 9 demonstrates another state of FIG. 8 after a solder reflow process.

As shown in FIG. 7, a second embodiment of the mask 2a in accordance with the present invention includes three holes 21a, located above and within the range of the metal structure 111 by having the via 112 as a center to be evenly arranged. As shown, the hole 21a is, but not limited to, a round shape. In other embodiments not shown herein, the hole 21a can also be shaped as a triangle, rectangle, or the like polygon.

As shown in FIG. 8 and FIG. 9, practically, while in applying the mask 2a to print a metal paste 3a onto the metal structure 111, the metal paste 3a is quite possible to be ill-planted or to jam the holes 21a, such that the position of the metal paste 3a on the metal structure 111 would be shifted from the design position. However, after the annealing of the solder reflow process is applied to the metal paste 3a on the metal structure 111, for the metal paste 3a would melt and thus flow due to the high temperature, the occupied area of the metal paste 3a on the metal structure 111 would increase. After the annealing, a corresponding anti-corrosion protective film 3a′ can be obtained by solidifying the melted metal paste 3a over the metal structure 111. The exposed area of the annual metal structure 111 to the atmosphere would be decreased, so that the metal structure 111 can have a better protection, by the anti-corrosion protective film 3a′ covering the metal structure 111, from being oxidized or vulcanized by the corresponding oxygen and sulfur in the atmosphere.

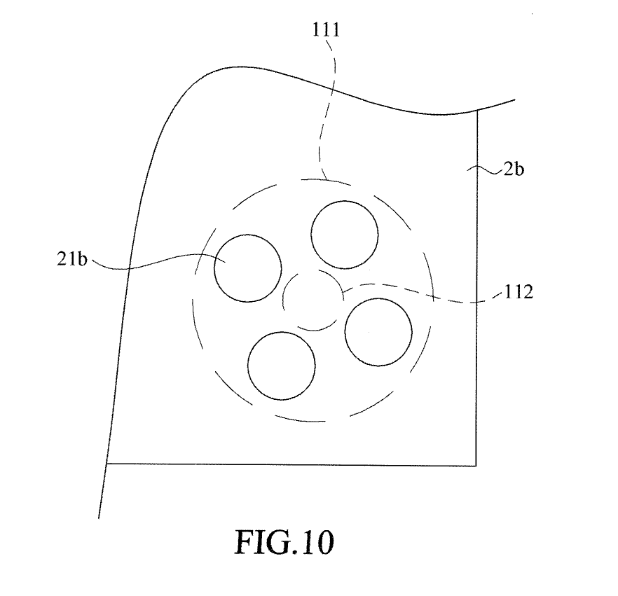

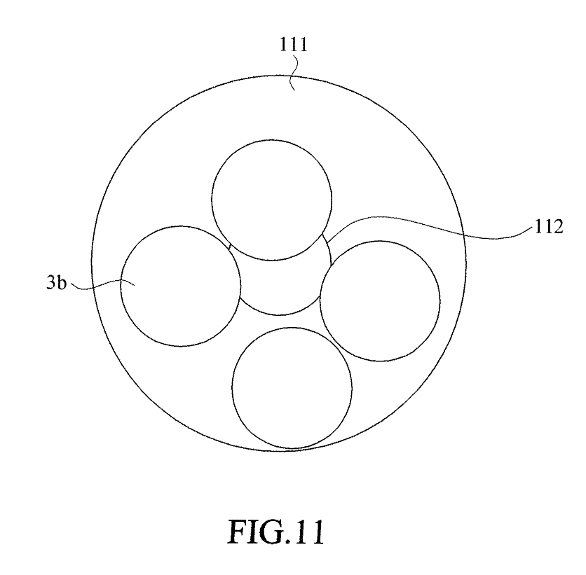

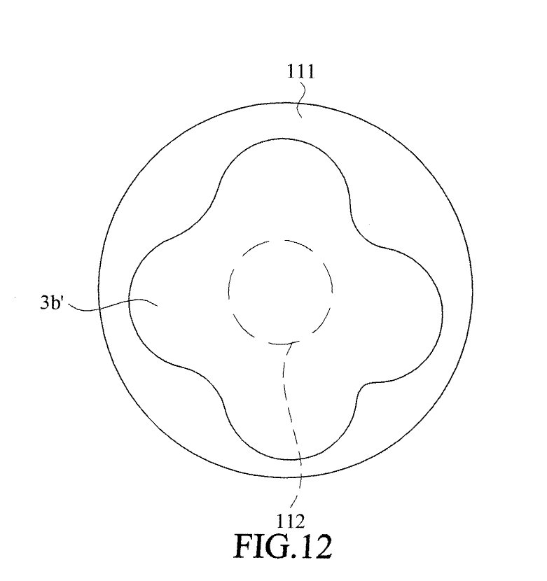

Refer now to FIG. 10 through FIG. 12, in which FIG. 10 shows a schematic planar view of a third embodiment of the mask in accordance with the present invention, FIG. 11 shows a schematic planar view of metal pastes printed on the test contact by applying the mask of FIG. 10, and FIG. 12 demonstrates another state of FIG. 9 after a solder reflow process.

As shown, the third embodiment of the mask 2b in accordance with the present invention includes four holes 21b for allowing the metal paste 3b to flow therethrough to the metal structure 111. By compared to the aforesaid two embodiments, the holes 21b of this embodiment has a smaller size, such that, within the same range of the metal structure 111, four separate holes 21 can be arranged. For the size of the hole 21b becomes smaller, the possibility of jamming hole would be definitely increased. However, after the annealing of the solder reflow process has been applied to the metal paste 3b over the metal structure 111, a broader anti-corrosion protective film 3b′ covering the metal structure 111 would be formed from the melted metal paste 3b so as to protect the metal structure 111 from been oxidized or vulcanized by the oxygen or sulfur in the atmosphere.

Accordingly, the method of forming an anti-corrosion protective film in accordance with the present invention is mainly to flow the metal paste through the holes of the mask positioned correspondingly to the test contact to be printed on the annual metal structure of the test contact, and then to apply the solder reflow process to melt the metal paste over the test contact so as to broaden the occupied area of the metal paste and thus to better protect the test contact from be oxidized or vulcanized.

Further, in other embodiments, the test contact of the substrate can have a test contact having only the metal structure but no via, and, under such a circumstance, the anti-corrosion protective film can be still formed in a structural pattern of the perimeter bump portion and the central concave portion to protect the test contact. By providing such a structural pattern of the anti-corrosion protective film, the probe for testing can easily pierce the central concave portion to contact electrically the metal structure located therebelow.

By compared to the conventional technique for improving the testing efficiency of the ICT, in which the test contact is not covered by any solder paste and thus the printed circuit board is actually exposed to the atmosphere containing the sulfur, the naked copper of the test contact would react with the sulfur to generate the Cu₂S, which is a harmful substance to the printed circuit board. On the other hand, the method of forming an anti-corrosion protective film provided by the present invention can effectively utilize the holes of the mask to print the metal paste onto the corresponding test contact of the substrate, and further apply the solder reflow process to melt the metal paste and thus enlarge the occupied area (i.e., the coverage) of the anti-corrosion protective film on the test contact so as to protect the test contact from any type of corrosion.

Practically, in the case that the mask has two holes, the cross section of each the hole would be larger so that a plenty of the metal paste can be printed onto the test contact. Yet, in this case, the usage of the metal paste might be higher. On the other hand, while the number of the holes on the mask is increased, the metal paste can be better distributed over the test contact and the usage thereof can be substantially reduced. However, the cross section of each the hole would be decreased, as the number of the holes is increased. Definitely, in such a circumstance, jamming of holes might be significant. Therefore, the viscosity of the metal paste needs to be adjusted so as to avoid severe hole jamming. It is noted that the anti-corrosion protective film provided by the present invention does not necessarily fully cover the test contact. Empirically, as an anti-corrosion protective film to completely cover the test contact is desired, the size of the hole on the mask shall be enlarged so as to increase the usage of the metal paste on the metal structure. Definitely, such an embodiment is still within the scope of the present invention. Further, the mask of the present invention can have a single hole; for example, a C-shape hole to match the annual metal structure, a square hole, a concentric polygonal hole, or any the like that can produce a structural pattern having a central concave portion and a perimeter bump portion to the melted metal paste over the test contact after the solder reflow process.

While the present invention has been particularly shown and described with reference to a preferred embodiment, it will be understood by those skilled in the art that various changes in form and detail may be without departing from the spirit and scope of the present invention.

What is claimed is:

1. A method of forming an anti-corrosion protective film, to form an anti-corrosion protective film on a test contact of a substrate, comprising the steps of:
(a) preparing a mask having at least one hole corresponding to the test contact;
(b) applying a printing process to print a metal paste onto the test contact through the at least one hole of the mask; and
(c) applying a solder reflow process onto the metal paste over the test contact so as to melt and then solidify the metal paste to form the anti-corrosion protective film covering the test contact.

2. The method of forming an anti-corrosion protective film of claim 1, wherein the test contact includes a metal structure and a via, the via being located at a center of the metal structure, the at least one hole of the being positioned respective to the metal structure so as to allow the metal paste to penetrate therethrough to print on the metal structure.

3. The method of forming an anti-corrosion protective film of claim 2, wherein the at least one hole is consisted of a plurality of holes that are symmetrically arranged.

4. The method of forming an anti-corrosion protective film of claim 1, wherein the metal paste is a solder paste.

5. A circuit board having an anti-corrosion protective film, comprising:
a substrate, having a test contact, the test contact further including a metal structure and a via located at a center of the metal structure; and
an anti-corrosion protective film, covering the test contact.

6. The circuit board having an anti-corrosion protective film of claim 5, wherein the anti-corrosion protective film further includes at least one perimeter bump portion and a central concave portion, the central concave portion being located right above the via.

7. The circuit board having an anti-corrosion protective film of claim 6, wherein the perimeter bump portion and the central concave portion are integrated as a unique piece, the perimeter bump portion being located above the metal structure.

8. A circuit board having an anti-corrosion protective film, comprising:
a substrate, having a test contact, the test contact further including a metal structure; and
an anti-corrosion protective film to cover the test contact.

9. The circuit board having an anti-corrosion protective film of claim 8, wherein the anti-corrosion protective film further includes at least one perimeter bump portion and a central concave portion, the central concave portion being located above the metal structure.

10. The circuit board having an anti-corrosion protective film of claim 9, wherein the perimeter bump portion and the central concave portion are integrated as a unique piece, the perimeter bump portion being located above the metal structure.
